(19) United States
(12) Patent Application Publication
(10) Pub. No.: US 2015/0171064 A1
(43) Pub. Date: Jun. 18, 2015

(54) PACKAGE ASSEMBLY AND METHOD FOR MANUFACTURING THE SAME

(71) Applicant: Silergy Semiconductor Technology (Hangzhou) Ltd., Hangzhou (CN)

(72) Inventor: Xiaochun Tan, Hangzhou (CN)

(21) Appl. No.: 14/567,342

(22) Filed: Dec. 11, 2014

(30) Foreign Application Priority Data
Dec. 12, 2013 (CN) 201310677107.5

(51) Int. Cl. H01L 25/16; H01L 23/00; H01L 21/56; H01L 21/48; H01L 23/528; H01L 23/31; H01L 21/768; H01L 23/495; H01L 25/00

(52) U.S. Cl. CPC H01L 25/165; H01L 23/4951; H01L 23/49582; H01L 24/03; H01L 24/09; H01L 24/11; H01L 24/17; H01L 23/49575; H01L 24/81; H01L 21/56; H01L 25/50; H01L 23/528; H01L 23/3107; H01L 21/768; H01L 21/4857; H01L 21/4842; H01L 2224/0905; H01L 2224/0951; H01L 2224/17106; H01L 2224/1705; H01L 2224/03013; H01L 2224/116; H01L 2224/81815; H01L 2224/80031; H01L 2224/08111; H01L 2924/14; H01L 2924/1304; H01L 2924/1205; H01L 2924/1206; H01L 2924/1207; H01L 2924/1203; H01L 2224/16112

(57) ABSTRACT

A package assembly and a method for manufacturing the same are disclosed. The package assembly includes a chip carrier having interconnect areas, solder disposed in the interconnect areas, and an electronic device having conductive bumps each of which has an end in contact with the solder. Thus, the electronic device is soldered to the chip carrier. The interconnect areas each have a recess for contacting and receiving the solder and securing respective one of the conductive bumps. When the solder flows during operation, the package assembly according to the present disclosure maintains a good electrical connection between the chip carrier and the electronic device, which results in a high reliability and a long lifetime.

### CLAIM OF PRIORITY

This application claims priority to Chinese Application No. 201310677107.5, filed Dec. 12, 2013 (published as CN 103633058A), which is hereby incorporated by reference.

### BACKGROUND OF THE INVENTION

1. Field of the Invention

The present disclosure relates to semiconductor technology, and more particularly, to a package assembly having a chip carrier and a method for manufacturing the same.

2. Description of the Related Art

A chip carrier is widely used in a package assembly. The chip carrier is, for example, a leadframe in the package assembly. A semiconductor chip is encapsulated in an encapsulant and electrically connected to external circuits by the leadframe. In other cases, the chip carrier is a printed circuit board. An integrated circuit chip is mounted on the printed circuit board and electrically connected to external circuits by the printed circuit board.

The package assembly in a flip-chip manner has attracted attention because it is small-size and light-weight, and has a high packaging density. FIGS. 1 and 2 are a perspective view and a cross sectional view of a package assembly 100 according to the prior art, respectively. A line AA is shown in FIG. 1, crossing interconnect areas 112 of a group of leads. The corresponding cross sectional view is taken along line AA.

In the package assembly 100, an integrated circuit chip 120 is mounted on a leadframe 110 in a flip-chip manner. The leadframe 110 includes a plurality of finger-like leads 111. Each of the leads 111 has an inward portion inside an encapsulant 160 and an outward portion extending outside the encapsulant 160. Conductive bumps 121 are provided at a lower surface of an integrated circuit chip 120, at the inward portions of the leads 111. Each of the conductive bumps 121 has an end soldered to an upper surface of respective one of the leads 111 by solder 122. The leadframe 110 and the integrated circuit chip 120 are encapsulated by the encapsulant 160. At least the outward portions of the leads 111 of the leadframe 110 are exposed from the encapsulant 160, for electric connection with external circuits, such as a PCB (i.e. printed circuit board). Interconnect areas 112 are formed at upper surfaces of the leads 111.

In the above package assembly 100 according to the prior art, local delamination occurs between the encapsulant 160 and the leadframe 110 during operation of the package assembly, due to poor adhesion between the encapsulant 160 and the leadframe 110 or moisture from the environment. Moreover, the solder 122 is reflowed unintendedly, away from the interconnect areas 112, due to heat generated during operation of electronic devices, which causes failure of an electrical connection between the integrated circuit chip 120 and the leadframe 110.

Thus, it is desirable that reliability and lifetime of the chip carrier and the package assembly are increased.

### BRIEF DESCRIPTION OF THE INVENTION

One object of the present disclosure is to provide a package assembly including a chip carrier which avoids failure of electronic devices during operation due to reflow of solder away from interconnect areas.

According to one aspect of the present disclosure, there is provided a package assembly comprising: a chip carrier having interconnect areas; solder disposed in the interconnect areas; and an electronic device having conductive bumps each of which has an end in contact with the solder so that the electronic device is soldered to the chip carrier, wherein the interconnect areas each have a recess for contacting and receiving the solder and securing respective one of the conductive bumps.

Preferably, the end of each of the conductive bumps is inserted into respective one of the interconnect areas.

Preferably, the chip carrier comprises a metal layer, and the interconnect areas are recesses at a surface of the metal layer.

Preferably, the end of each of the conductive bumps has a bottom surface lower than a main surface of the metal layer.

Preferably, each of the interconnect areas has a surface with a shape of an inner surface of one selected from a group consisting of a hemisphere, a cubic, a cuboid, and a cylinder.

Preferably, the package assembly further comprises an encapsulant which covers at least a portion of the chip carrier.

Preferably, the encapsulant covers at least a portion of the electronic device.

Preferably, the chip carrier is one selected from a group consisting of a leadframe and a printed circuit board.

Preferably, the chip carrier is a printed circuit board comprising an insulation substrate and conductive traces, and the interconnect areas are recesses at surfaces of the conductive traces.

Preferably, the electronic devices comprise at least one selected from a group consisting of an integrated circuit chip and a discrete component.

Preferably, the discrete components comprise at least one selected from a group consisting of a resistor, a capacitor, an inductor, a diode and a transistor.

Preferably, wherein the integrated circuit chips are mounted on the chip carrier in a flip-chip manner.

According to another aspect of the present disclosure, there is provided a method for manufacturing a package assembly, comprising: forming a chip carrier having interconnect areas each of which has a recess at a surface; disposing solder in the interconnect areas of the chip carrier so that the interconnect areas contact and receive at least a portion of the solder; disposing an electronic device having conductive bumps on the chip carrier, each of the conductive bumps having an end in contact with the solder; and reflowing the solder so that the electronic device is soldered to the chip carrier.

Preferably, the end of each of the conductive bumps is inserted into respective one of the interconnect areas.

Preferably, the step of forming the chip carrier comprises: forming interconnect areas each of which has a recess at a surface of the metal layer; and patterning the metal layer into leads so that the interconnect areas are located at surfaces of the leads and adjacent ones of the leads are separated from each other by trenches.

Preferably, the interconnect areas are formed by one etching process, and the metal layer is patterned by the other etching process.

Preferably, the interconnect areas are formed simultaneously with patterning the metal layer by a stamping process.

Preferably, the interconnect areas are formed by an etching process, and the metal layer is patterned by a stamping process.

Preferably, the step of forming the chip carrier comprises: forming a metal layer on an insulation substrate, the metal layer having interconnect areas each of which has a recess at a surface of the metal layer; and patterning the metal layer into conductive traces so that the interconnect areas are located at surfaces of the conductive traces and adjacent ones of the conductive traces are separated from each other by trenches.

Preferably, the step of forming the metal layer comprises: forming recesses at a surface of an insulation substrate; and forming a metal layer on the insulation substrate by plating, wherein the metal layer is conformal at the recesses of the surface of the insulation substrate so that recesses are formed at the surface of the metal layer as the interconnect areas.

Preferably, the step of forming the metal layer comprises: forming a metal layer on an insulation substrate by plating; and forming recesses at a surface of the metal layer as the interconnect areas, by stamping the metal layer and a portion of the insulation substrate below the metal layer.

Preferably, the metal layer is patterned by an etching process.

In the package assembly having the chip carrier according to the present disclosure, the interconnect areas each have a recessed surface for contacting and receiving the solder while securing respective one of the conductive bumps. Preferably, the end of each of the conductive bumps is inserted into respective one of the interconnect areas. Each of the interconnect areas has a bottom surface lower than a main surface of the chip carrier. Consequently, at least a portion of the solder remains in the interconnect areas, without flowing away therefrom, even in a case that the solder is melted due to heat generated during operation. Meanwhile, the interconnect areas limit lateral movement of the conductive bumps. The package assembly according to the present disclosure maintains a good electrical connection between the chip carrier and the electronic device, even in a case that an amount of the solder is reduced by reflowing, which results in a high reliability and a long lifetime.

### BRIEF DESCRIPTION OF THE DRAWINGS

The above and other objects, advantages and features of the present invention will become more fully understood from the detailed description given hereinbelow in connection with the appended drawings, and wherein:

FIG. 1 is a perspective view showing a flip-chip package assembly according to the prior art;

FIG. 2 is a cross sectional view showing a flip-chip package assembly according to the prior art;

FIG. 3 is a perspective view showing a leadframe according to a first embodiment of the present disclosure;

FIG. 4A is a top view and FIGS. 4B-C are cross sectional views showing a leadframe according to a first embodiment of the present disclosure;

FIG. 5 is a perspective view showing a package assembly according to a second embodiment of the present disclosure;

FIG. 6 is a cross sectional view showing a package assembly according to a second embodiment of the present disclosure;

FIGS. 7A-G are cross sectional views showing various steps of a method for manufacturing a package assembly according to a third embodiment of the present disclosure;

FIG. 8 is a perspective view showing a printed circuit board according to a fourth embodiment of the present disclosure;

FIG. 9A is a top view and FIGS. 9B-C are cross sectional views showing a printed circuit board according to a fourth embodiment of the present disclosure;

FIG. 10 is a perspective view showing a package assembly according to a fifth embodiment of the present disclosure;

FIG. 11 is a cross sectional view showing a package assembly according to a fifth embodiment of the present disclosure; and

FIGS. 12A-G are cross sectional views showing various steps of a method for manufacturing a package assembly according to a sixth embodiment of the present disclosure.

### DETAILED DESCRIPTION OF EMBODIMENTS OF THE INVENTION

Exemplary embodiments of the present disclosure will be described in more details below with reference to the accompanying drawings. In the drawings, like reference numerals denote like members. The figures are not drawn to scale, for the sake of clarity. For simplicity, the package structure having been subject to several relevant process steps may be shown in one figure.

It should be understood that when one layer or region is referred to as being “above” or “on” another layer or region in the description of the package structure, it can be directly above or on the other layer or region, or other layers or regions may be intervened therebetween. Moreover, if the device in the figures is turned over, the layer or region will be “under” or “below” the other layer or region. In contrast, when one layer is referred to as being “directly on” or “on and adjacent to” or “adjoin” another layer or region, there are not intervening layers or regions present.

Some particular details of the present disclosure will be described below, such as exemplary structures, materials, dimensions, process steps and technologies of the package assembly, for better understanding of the present disclosure. However, it can be understood by one skilled person in the art that these details are not always essential for but can be varied in a specific implementation of the disclosure.

In the present disclosure, the term “electronic device” is not limited to integrated circuit chips, but should be understood in a broad sense as any packed objects, including both integrated circuit chips and discrete components. The discrete components include at least one selected from a group consisting of a resistor, a capacitor, an inductor, a diode and a transistor.

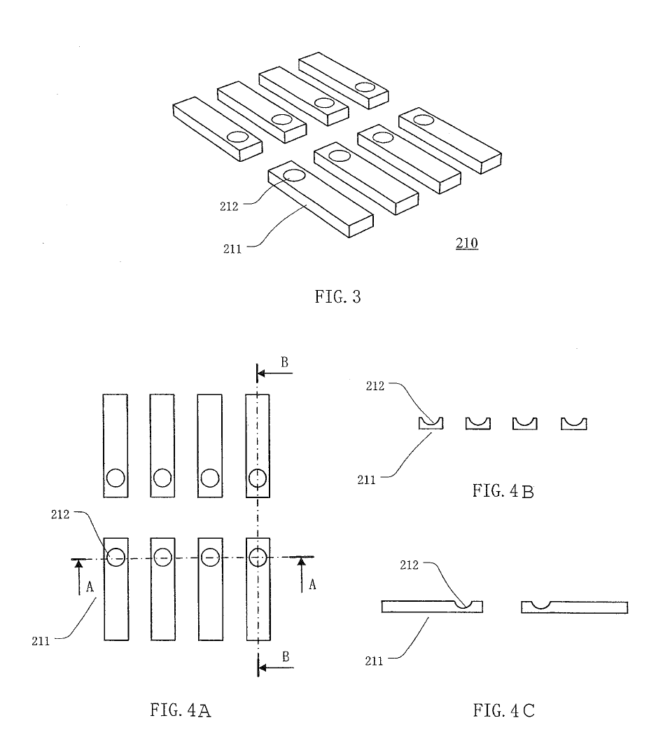

FIG. 3 is a perspective view showing a leadframe 210 according to a first embodiment according to the present disclosure. FIG. 4A is a top view and FIGS. 4B-C are cross sectional views of the leadframe 210. A line AA and a line BB are shown in FIG. 4A to indicate where cross sectional views in FIGS. 4B and 4C are taken respectively. Line AA crosses a group of leads arranged in a row. Line BB crosses a group of leads arranged in a column, and is substantively perpendicular to line AA.

The leadframe 210 includes at least one finger-like lead 211. In an example, the leadframe 210 includes 8 leads 211, with every group of 4 leads arranged in a row and every group of 2 leads arranged in a column. Each of the leads 211 has an interconnect area 212 at an upper surface of its inward portion. The interconnect areas 212 each have a recess for contacting and receiving the solder and securing respective one of the conductive bumps.

It should be noted that the interconnect areas 212 are shown in FIGS. 3 and 4A-C as each having a surface with a shape of an inner surface of a hemisphere, which, however, is not essential. Alternatively, the interconnect areas 212 may each have a surface with a shape of an inner surface of one selected from a group consisting of a cubic, a cuboid, and a cylinder, or any shape suitable for providing a space for receiving the solder.

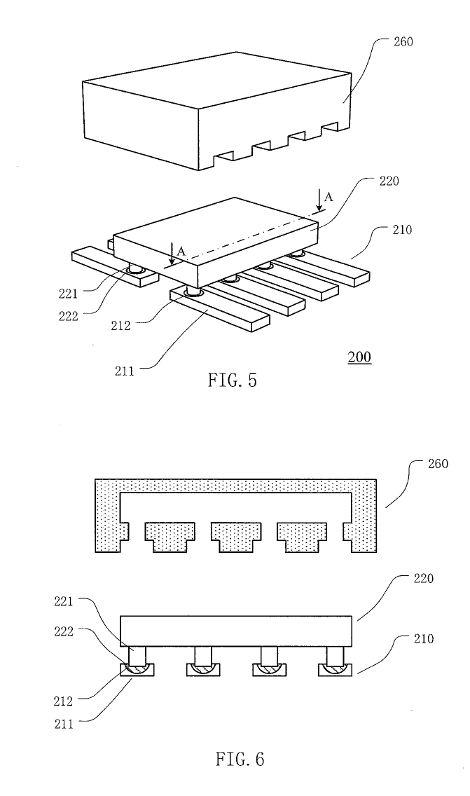

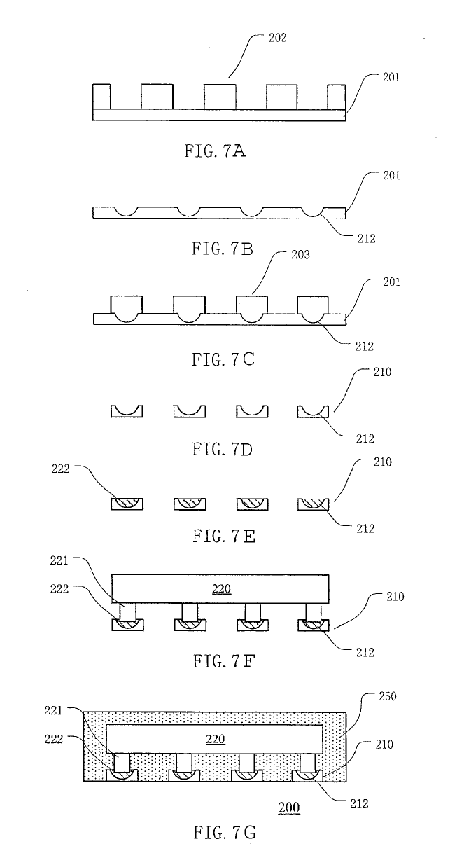

FIGS. 5 and 6 are a perspective view and a cross sectional view showing a package assembly 200 according to a second embodiment of the present disclosure. A line AA is shown in FIG. 5 to indicate where cross sectional views in FIGS. 6 and 7A-G are taken. Line AA crosses a group of leads arranged in a row.

The chip carrier is, for example, a leadframe 210 in the package assembly 200. The integrated circuit chip 220 includes internal circuits and a plurality of conductive bumps 221 which are electrically coupled to the internal circuits. An integrated circuit chip 220 is mounted on the leadframe 210. The leadframe 210 includes a plurality of finger-like leads 211. Each of the leads 211 has an inward portion inside an encapsulant 260 and an outward portion extending outside the encapsulant 260. Conductive bumps 221 are provided at a lower surface of an integrated circuit chip 220, at the inward portions of the leads 211. Each of the conductive bumps 221 has an end which is inserted into solder 222, so that the conductive bumps 221 are soldered to respective ones of the leads 211 by the solder 222. The leadframe 210 and the integrated circuit chip 220 are encapsulated by the encapsulant 260. In an example, the encapsulant 260 may be one selected from a group consisting of a molding compound, a ceramic and a metal. In a case that the encapsulant 260 is a metal, an additional insulation layer may be provided between the encapsulant 260 and the leadframe 210 and between the encapsulant 260 and the integrated circuit chip 220 for electrical insulation. At least the outward portions of the leads 211 of the leadframe 210 are exposed from the encapsulant 260, for electric connection with external circuits, such as a PCB (i.e. printed circuit board).

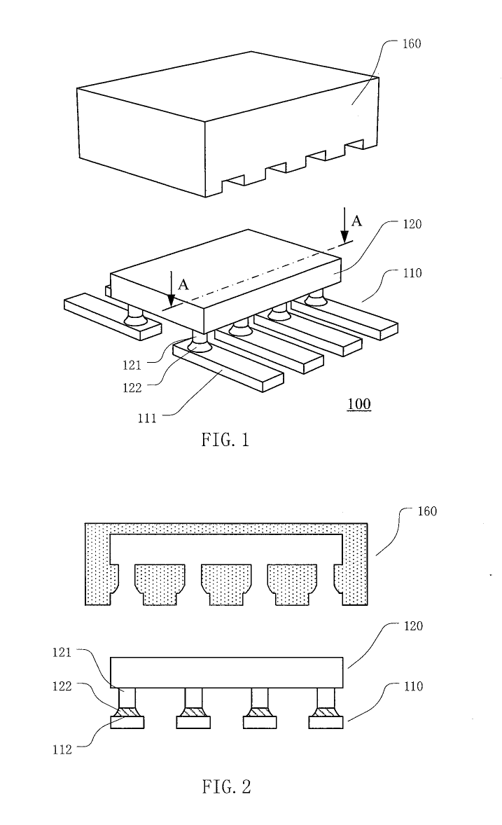

Different from the package assembly 100 shown in FIG. 1, each of the leads 211 has an interconnect area 212 at an upper surface of its inward portion in the package assembly 200 according to the present disclosure, as mentioned above. The interconnect areas 212 each have a recess for contacting and receiving the solder and securing respective one of the conductive bumps 221. Preferably, the end of each of the conductive bumps 221 is inserted into respective one of the interconnect areas 212. That is, each of the conductive bumps 221 has a bottom surface at its end lower than a main surface of respective one of the leads 211 of the leadframe 210. Even in a case that the package assembly 200 is unintendedly reflowed during operation, at least a portion of the solder 222 maintains in situ in the interconnect areas 212. The interconnect areas 212 limit lateral movement of the conductive bumps 221. Even in a case that an amount of the solder 222 is reduced, the conductive bumps 221 maintain in situ. The package assembly according to the present disclosure maintains a good electrical connection between the leadframe 210 and the integrated circuit chip 220, which results in a high reliability and a long lifetime.

It should be noted that the package assembly 200 is described in the above embodiments as having the encapsulant 260, which, however, is not essential. Alternatively, the package assembly 200 may have no encapsulant 260.

Still alternatively, the encapsulant 260 covers only a portion of the leadframe 210 in the package assembly 200, for example, the portion of the leadframe that is located below the integrated circuit chip 220. The encapsulant 260 may not cover the integrated circuit chip 220. Still alternatively, the encapsulant 260 covers a portion of the leadframe 210 and a portion of the integrated circuit chip 220. For example, the encapsulant 260 covers side walls of the integrated circuit chip 220 and the portion below the integrated circuit chip 220.

Still alternatively, the leads 211 of the leadframe 210 in the package assembly 200 may have only inward portions inside the encapsulant 260, without outward portions. Bottom surfaces of the leads 211 are exposed at the bottom of the encapsulant 260, for electric connection with external circuits, such as a PCB (i.e. printed circuit board).

FIG. 7A-G are cross sectional views showing various steps of a method for manufacturing a package assembly according to a third embodiment of the present disclosure. The method is an example for manufacturing the package assembly 200 according to the second embodiment of the present disclosure.

The method is started with a metal sheet 201 (for example, a copper sheet). A first photoresist mask 202 is formed on the metal sheet 201, with openings which expose portions of the metal sheet 201, as shown in FIG. 7A. The metal sheet 201 is etched through the first photoresist mask 202 to form interconnect areas 212 having recessed surfaces, by decreasing a thickness of the exposed portions of the metal sheet 201. After etching, the first photoresist mask 202 is removed, as shown in FIG. 7B. A second photoresist mask 203 is formed again on the metal sheet 201, with openings formed therein to define shapes of the leads while shielding the interconnect areas 212, as shown in FIG. 7C. The metal sheet 201 is etched through the second photoresist mask 203 and patterned into the leads 211 of stripes, by completely removing exposed portions of the metal sheet 201. Adjacent ones of the leads 211 are separated from each other by trenches. After etching, the second photoresist mask 203 is removed and a leadframe 210 is formed, as shown in FIG. 7D. Solder 222 is disposed in the interconnect areas 212 of the leadframe 210 so that the interconnect areas 212 contact and receive the solder 222, as shown in FIG. 7E. An integrated circuit chip 220 having conductive bumps 221 is disposed on the leadframe 210. Each of the conductive bumps 221 has an end for contacting the solder 222. The solder 222 is reflowed so that the integrated circuit chip 220 is soldered to the leadframe 210, as shown in FIG. 7F. An encapsulant 260 covers at least portions of the integrated circuit chip 220 and the leadframe 210 to form a package assembly 200, as shown in FIG. 7G.

Alternatively, instead of the step of forming the second photoresist mask 203 and subsequent steps, which are shown in FIGS. 7C to 7D, the trenches are formed by stamping using a suitable mold, for separating adjacent ones of the leads 211 and defining the leads 211 of stripes.

Still alternatively, another method for manufacturing a package assembly may be started with a metal sheet (for example, a copper sheet). The leadframe 210 according to the first embodiment of the present disclosure is formed by one stamping process using a suitable mold.

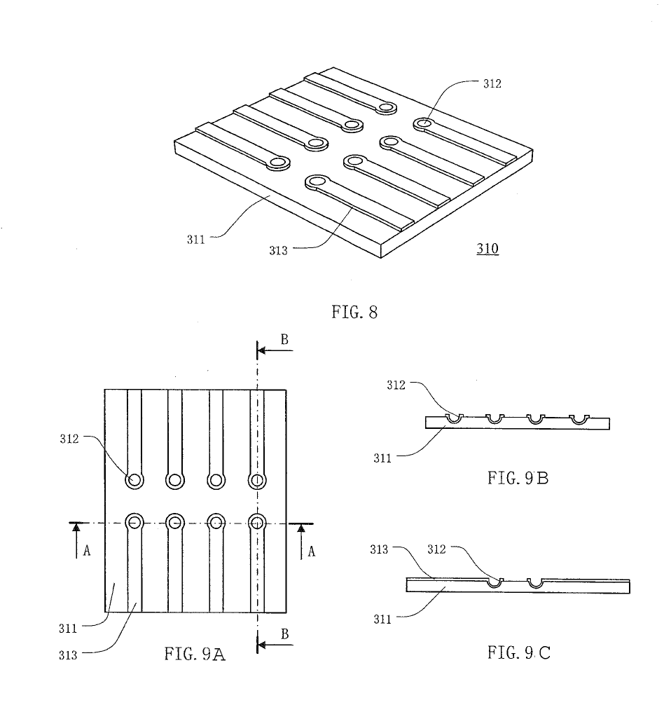

FIG. 8 is a perspective view showing a printed circuit boards 310 according to a fourth embodiment according to the present disclosure. FIG. 9A is a top view and FIGS. 9B-C are cross sectional views of the printed circuit boards 310. A line AA and a line BB are shown in FIG. 9A to indicate where cross sectional views in FIGS. 9B and 9C are taken respectively. Line AA crosses a group of conductive traces arranged in a row. Line BB crosses a group of conductive traces arranged in a column, and is substantively perpendicular to line AA.

The printed circuit board 310 includes an insulation substrate 311, and at least one conductive trace 313 on the insulation substrate 311. For example, the insulation substrate 311 is made of polyester resin. For example, the conductive traces 313 are copper traces. In an example, the printed circuit board 310 includes 8 conductive traces 313, with every group of 4 traces arranged in a row and every group of 2 traces arranged in a column. Each of the conductive traces 313 has an interconnect area 312 at an upper surface. The interconnect areas 312 each have a recess for contacting and receiving the solder and securing respective one of the conductive bumps. Preferably, the insulation substrate 311 also has recesses corresponding to the interconnect areas 312. The conductive traces 313 are conformal on the insulation substrate 311. Thus, the interconnect areas 312 are formed corresponding to the recesses of the insulation substrate 311.

It should be noted that the interconnect areas 312 are shown in FIGS. 8 and 9A-C as each having a surface with a shape of an inner surface of a hemisphere, which, however, is not essential. Alternatively, the interconnect areas 312 may each have a surface with a shape of an inner surface of one selected from a group consisting of a cubic, a cuboid, and a cylinder, or any shape suitable for providing a space for receiving the solder.

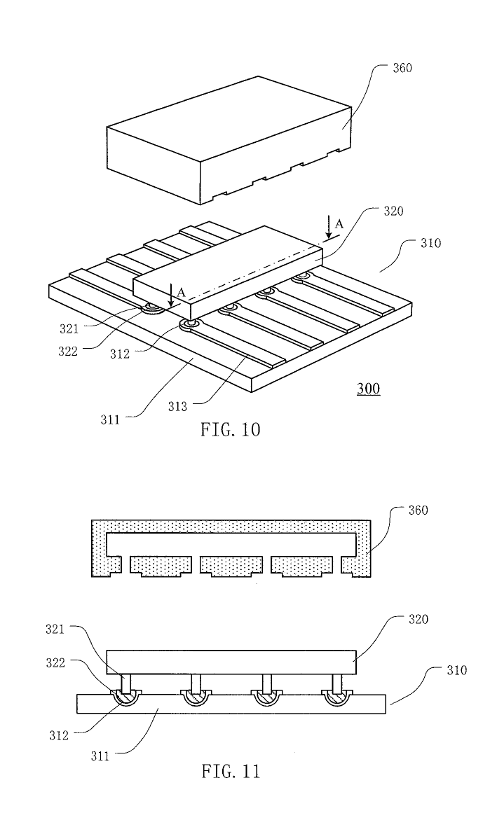

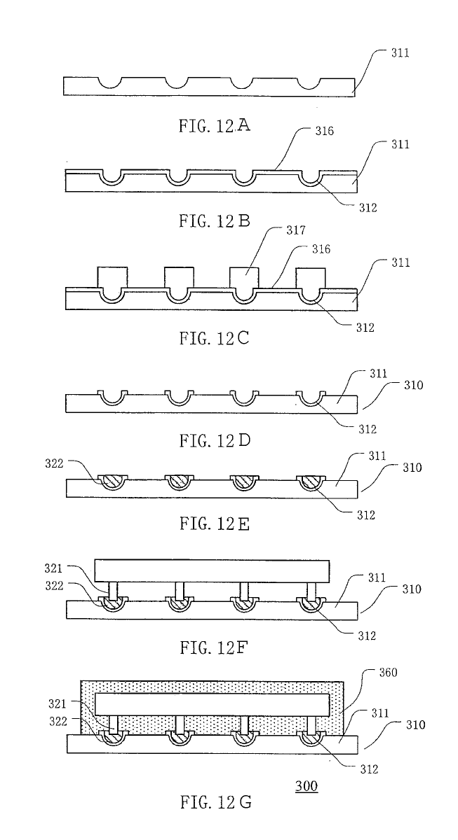

FIGS. 10 and 11 are a perspective view and a cross sectional view showing a package assembly 300 according to a fifth embodiment of the present disclosure. A line AA is shown in FIG. 10 to indicate where cross sectional views in FIGS. 11 and 12A-G are taken. Line AA crosses a group of conductive traces arranged in a row.

The chip carrier is, for example, a printed circuit board 310 in the package assembly 300. The integrated circuit chip 320 includes internal circuits and a plurality of conductive bumps 321 which are electrically coupled to the internal circuits. An integrated circuit chip 320 is mounted on the printed circuit board 310. The printed circuit board 310 includes an insulation substrate 311, and at least one conductive trace 313 on the insulation substrate 311. For example, the insulation substrate 311 is made of polyester resin. For example, the conductive traces 313 are copper traces. Each of the conductive traces 313 has an inward portion inside an encapsulant 360 and an outward portion extending outside the encapsulant 360. Conductive bumps 321 are provided at a lower surface of an integrated circuit chip 320, at the inward portions of the conductive traces 313. Each of the conductive bumps 321 has an end which is inserted into solder 322, so that the conductive bumps 321 are soldered to respective ones of the conductive traces 313 by the solder 322. The printed circuit board 310 and the integrated circuit chip 320 are encapsulated by the encapsulant 360. In an example, the encapsulant 360 may be one selected from a group consisting of a molding compound, a ceramic and a metal. In a case that the encapsulant 360 is a metal, an additional insulation layer may be provided between the encapsulant 360 and the printed circuit board 310 and between the encapsulant 360 and the integrated circuit chip 320 for electrical insulation. At least the outward portions of the conductive traces 313 of the printed circuit board 310 are exposed from the encapsulant 360, for electric connection with external circuits, such as a PCB (i.e. printed circuit board).

Different from the package assembly 100 shown in FIG. 1, each of the conductive traces 313 has an interconnect area 312 at an upper surface of its inward portion in the package assembly 300 according to the present disclosure, as mentioned above. The interconnect areas 312 each have a recess for contacting and receiving the solder and securing respective one of the conductive bumps 321. Preferably, the end of each of the conductive bumps 321 is inserted into respective one of the interconnect areas 312. That is, each of the conductive bumps 321 has a bottom surface at its end lower than a main surface of respective one of the leads 313 of the leadframe 310. Even in a case that the package assembly 300 is unintendedly reflowed during operation, at least a portion of the solder 322 maintains in situ in the interconnect areas 312. The interconnect areas 312 limit lateral movement of the conductive bumps 321. Even in a case that an amount of the solder 322 is reduced, the conductive bumps 321 maintain in situ. The package assembly according to the present disclosure maintains a good electrical connection between the leadframe 310 and the integrated circuit chip 320, which results in a high reliability and a long lifetime.

It should be noted that the package assembly 300 is described in the above embodiments as having the encapsulant 360, which, however, is not essential. Alternatively, the package assembly 300 may have no encapsulant 360.

Still alternatively, the encapsulant 360 covers only a portion of the printed circuit board 310 in the package assembly 300, for example, the portion of the printed circuit board that is located below the integrated circuit chip 320. The encapsulant 306 may not cover the integrated circuit chip 320. Still alternatively, the encapsulant 360 covers a portion of the printed circuit board 310 and a portion of the integrated circuit chip 320. For example, the encapsulant 260 covers side walls of the integrated circuit chip 320 and the portion below the integrated circuit chip 320.

FIGS. 12A-G are cross sectional views showing various steps of a method for manufacturing a package assembly according to a sixth embodiment of the present disclosure. The method is an example for manufacturing the package assembly 300 according to the fifth embodiment of the present disclosure.

The method is started with an insulation substrate 311 (for example, a polyester resin board) having preformed recesses, as shown in FIG. 12A. A metal layer 316 is formed on the insulation substrate 311 by plating, wherein the metal layer 316 is conformal at the recesses of the insulation substrate 311, as shown in FIG. 12B. A photoresist mask 317 is formed on the metal layer 316, as shown in FIG. 12C. The photoresist mask 317 contains a pattern for defining regions where conductive traces and interconnect areas will be formed. The photoresist mask 317 shields at least the recesses of the insulation substrate 311 for forming the interconnect areas. The metal layer 316 is etched through the photoresist mask 317 and patterned into the conductive traces 313 and interconnect areas 312, by completely removing exposed portions of the metal layer 316. Adjacent ones of the conductive traces 313 are separated from each other by trenches. After etching, the photoresist mask 317 is removed, and a printed circuit board 310 is formed, as shown in FIG. 12D. Solder 322 is disposed in the interconnect areas 312 of the printed circuit board 310 so that the interconnect areas 312 contact and receive the solder 322, as shown in FIG. 12E. An integrated circuit chip 320 having conductive bumps 321 is disposed on the printed circuit board 310. Each of the conductive bumps 321 has an end for contacting the solder 322. The solder 322 is reflowed so that the integrated circuit chip 320 is soldered to the printed circuit board 310, as shown in FIG. 12F. An encapsulant 360 covers at least portions of the integrated circuit chip 320 and the printed circuit board 310 to form a package assembly 300, as shown in FIG. 12G.

Alternatively, instead of the steps of forming the printed circuit board 310 in the above method, which are shown in FIGS. 12A-D, a metal layer is formed on an insulation substrate by plating, and recesses are formed by stamping the metal layer and a portion of the insulation substrate below the metal layer. The steps shown in FIGS. 12E-G are then performed to form the package assembly 300.

It should also be understood that the relational terms such as “first”, “second”, and the like are used in the context merely for distinguishing one element or operation form the other element or operation, instead of meaning or implying any real relationship or order of these elements or operations. Moreover, the terms “comprise”, “comprising” and the like are used to refer to comprise in nonexclusive sense, so that any process, approach, article or apparatus relevant to an element, if follows the terms, means that not only said element listed here, but also those elements not listed explicitly, or those elements inherently included by the process, approach, article or apparatus relevant to said element. If there is no explicit limitation, the wording “comprise a/an . . . ” does not exclude the fact that other elements can also be included together with the process, approach, article or apparatus relevant to the element.

Although various embodiments of the present invention are described above, these embodiments neither present all details, nor imply that the present invention is limited to these embodiments. Obviously, many modifications and changes may be made in light of the teaching of the above embodiments. These embodiments are presented and some details are described herein only for explaining the principle of the invention and its actual use, so that one skilled person can practice the present invention and introduce some modifications in light of the invention. The invention is intended to cover alternatives, modifications and equivalents that may be included within the spirit and scope of the invention as defined by the appended claims.

What is claimed is:

1. A package assembly comprising:
a chip carrier having interconnect areas;
solder disposed in said interconnect areas; and
an electronic device having conductive bumps each of which has an end in contact with said solder so that said electronic device is soldered to said chip carrier,
wherein said interconnect areas each have a recess for contacting and receiving said solder and securing respective one of said conductive bumps.

2. The package assembly according to claim 1, wherein said end of each of said conductive bumps is inserted into respective one of said interconnect areas.

3. The package assembly according to claim 1, wherein said chip carrier comprises a metal layer, and said interconnect areas are recesses at a surface of said metal layer.

4. The package assembly according to claim 3, wherein said end of each of said conductive bumps has a bottom surface lower than a main surface of said metal layer.

5. The package assembly according to claim 1, wherein each of said interconnect areas has a surface with a shape of an inner surface of one selected from a group consisting of a hemisphere, a cubic, a cuboid, and a cylinder.

6. The package assembly according to claim 1, further comprising an encapsulant which covers at least a portion of said chip carrier.

7. The package assembly according to claim 6, wherein said encapsulant covers at least a portion of said electronic device.

8. The package assembly according to claim 1, wherein said chip carrier is one selected from a group consisting of a leadframe and a printed circuit board.

9. The package assembly according to claim 8, wherein said chip carrier is a printed circuit board comprising an insulation substrate and conductive traces, and said interconnect areas are recesses at surfaces of said conductive traces.

10. The package assembly according to claim 1, wherein said electronic devices comprise at least one selected from a group consisting of integrated circuit chips and discrete components.

11. The package assembly according to claim 10, wherein said discrete components comprise at least one selected from a group consisting of a resistor, a capacitor, an inductor, a diode and a transistor.

12. The package assembly according to claim 10, wherein said integrated circuit chips are mounted on said chip carrier in a flip-chip manner.

13. A method for manufacturing said package assembly according to any of claim 1, comprising:
forming a chip carrier having interconnect areas each of which has a recess at a surface;
disposing solder in said interconnect areas of said chip carrier so that said interconnect areas contact and receive at least a portion of said solder;
disposing an electronic device having conductive bumps on said chip carrier, each of said conductive bumps having an end in contact with said solder; and
reflowing said solder so that said electronic device is soldered to said chip carrier.

14. The method according to claim 13, wherein said end of each of said conductive bumps is inserted into respective one of said interconnect areas.

15. The method according to claim 13, wherein said step of forming said chip carrier comprises:
forming interconnect areas each of which has a recess at a surface of said metal layer; and
patterning said metal layer into leads so that said interconnect areas are located at surfaces of said leads and adjacent ones of said leads are separated from each other by trenches.

16. The method according to claim 15, wherein said interconnect areas are formed by one etching process, and said metal layer is patterned by said other etching process.

17. The method according to claim 15, wherein said interconnect areas are formed simultaneously with patterning said metal layer by a stamping process.

18. The method according to claim 15, wherein said interconnect areas are formed by an etching process, and said metal layer is patterned by a stamping process.

19. The method according to claim 13, wherein said step of forming said chip carrier comprises:
forming a metal layer on an insulation substrate, said metal layer having interconnect areas each of which has a recess at a surface of said metal layer; and
patterning said metal layer into conductive traces so that said interconnect areas are located at surfaces of said conductive traces and adjacent ones of said conductive traces are separated from each other by trenches.

20. The method according to claim 19, wherein said step of forming said metal layer comprises:
forming recesses at a surface of an insulation substrate; and
forming a metal layer on said insulation substrate by plating, wherein said metal layer is conformal at said recesses of said surface of said insulation substrate so that recesses are formed at said surface of said metal layer as said interconnect areas.

21. The method according to claim 19, wherein said step of forming said metal layer comprises:
forming a metal layer on an insulation substrate by plating; and
forming recesses at a surface of said metal layer as said interconnect areas, by stamping said metal layer and a portion of said insulation substrate below said metal layer.

22. The method according to claim 19, wherein said metal layer are patterned by an etching process.
